(19) United States
(12) Patent Application Publication
(10) Pub. No.: US 2006/0038189 A1
(43) Pub. Date: Feb. 23, 2006

(54) Hermetically sealed packages and their method of manufacture

(76) Inventors: Calvin T. Coffey, Watkins Glen, NY (US); Dominick J. Forenz, Hammondsport, NY (US); Noshir B. Havewala, Painted Post, NY (US); David M. Lineman, Paintd Post, NY (US); C. Damon Osterhout, Beaver Dams, NY (US)

Correspondence Address: CORNING INCORPORATED, SP-TI-3-1, CORNING, NY, 14831, US

(21) Appl. No.: 10/921,624

(22) Filed: Aug. 18, 2004

(51) Int. Cl. H01L 33/00; H01L 21/20

(52) U.S. Cl. 257/88; 438/584

(57) ABSTRACT

A device includes a temperature-sensitive material disposed between a first substrate and a second substrate. A metal-containing seal is disposed perimetrically between the first and second substrates. In addition, a method of forming a device includes providing a temperature-sensitive material between a first substrate and a second substrate. The method also includes applying an electromagnetic field, which inductively heats a metal-containing material that is disposed between the first and second substrates without heating the temperature sensitive material to a temperature greater than a threshold temperature.

### BACKGROUND

Display devices are employed in disparate applications including entertainment and computer monitors to cell phones and personal digital assistants, to name only a few. While liquid crystal (LC) and plasma-based displays dominate many of the emerging technologies, there are certain drawbacks that have lead to interest in other display technologies.

One technology that has garnered significant interest as an alternative to LCD and plasma devices is based on organic light emitting diodes (OLEDs). OLEDs often are made from electroluminescent polymers and small-molecule structures. For example, OLEDs in an array may provide an alternative to liquid crystal (LC) based displays, because the LC materials and structures tend to be more complicated in form and implementation.

Beneficially, OLED-based displays do not require a light source (backlight) as needed in LC displays. OLEDs are a self-contained light source, and as such are much more compact while remaining visible under a wider range of conditions. Moreover, unlike LC displays which rely on a fixed cell gap, OLED-based displays can be flexible.

While OLEDs provide a light source for display and other applications with at least the benefits referenced above, there are certain considerations and limitations that can reduce their practical implementation. One issue to be considered when using OLED materials is their susceptibility to environmental contamination. In particular, exposure of an OLED display to water vapor or oxygen can be deleterious to the organic material and the structural components of the OLED. As to the former, the exposure to water vapor and oxygen can reduce the light emitting capability of the organic electroluminescent material itself. As to the latter, for example, exposure of the reactive metal cathode commonly used in OLED displays to these contaminants can over time result in ‘dark-spot’ areas and reduce the useful life of the OLED device. Accordingly, it is beneficial to protect OLED displays and their constituent components and materials from exposure to environmental contaminants such as water vapor and oxygen.

In order to minimize environmental contamination, OLEDs must be sealed between two layers, which are often glass. Often, the glass layers are sealed using epoxy adhesives or using laser-sealing techniques. These methods have met with mixed success. For example, the seals are often ineffective, or the temperatures of the sealing processes are damaging to the OLED material, or both.

What is needed therefore is a method of sealing the glass substrates to form a hermetically sealed OLED structure that overcomes at least the shortcomings described above.

### SUMMARY

In accordance with an example embodiment, a device includes a temperature-sensitive material disposed between a first substrate and a second substrate. A metal-containing seal is disposed perimetrically between the first and second substrates.

In accordance with another example embodiment, a method of forming a device includes providing a temperature-sensitive material between a first substrate and a second substrate. The method also includes applying an electromagnetic field, which inductively heats a metal-containing material that is disposed between the first and second substrates without heating the temperature sensitive material to a temperature greater than a threshold temperature.

### BRIEF DESCRIPTIONS OF THE DRAWINGS

The exemplary embodiments are best understood from the following detailed description when read with the accompanying drawing figures. It is emphasized that the various features are not necessarily drawn to scale. Thus, the dimensions may be arbitrarily increased or decreased for clarity of discussion.

FIG. 1 is a top view of a sealed display structure in accordance with an example embodiment.

FIG. 2 is a cross-sectional view of the structure of FIG. 1 taken along the line 2-2.

FIG. 3 is a partial cross-sectional view of the illustrative layers useful in sealing two substrates together in accordance with an example embodiment.

FIG. 4 is a schematic diagram of an apparatus for inductive sealing in accordance with an example embodiment.

FIG. 5 is a top view of an induction coil disposed over a substrate in accordance with an example embodiment.

### DETAILED DESCRIPTION

In the following detailed description, for purposes of explanation and not limitation, example embodiments disclosing specific details are set forth in order to provide a thorough understanding of the present invention. However, it will be apparent to one having ordinary skill in the art, having had the benefit of the present disclosure, that the present invention may be practiced in other embodiments that depart from the specific details disclosed herein. Moreover, descriptions of well-known devices, methods and materials may be omitted so as to not obscure the description of the present invention. Finally, it is noted that wherever practical, like reference numerals refer to like features.

In the example embodiments described herein, structures for use display and lighting OLED applications are set forth in significant detail. The display structures of the example embodiments may be used in computer monitors, PDA's, phone displays, to name only a few applications. The lighting structures of the example embodiments may be used in consumer and entertainment goods, to name only a few applications as well. It is noted, however, that this is merely an illustrative implementation of the methods and apparati of the described embodiments. To wit, the described illustrative embodiments are applicable to other technologies that are susceptible to similar problems as those described above. For example, the embodiments described herein may also be applied to sealing other materials and structures such as those used in displays, electronics and photonics. Characteristically, the embodiments describe may provide hermetic sealing of devices and materials that are susceptible to damage above a threshold temperature, which is not exceeded using the sealing methods and apparati of the example embodiments . . .

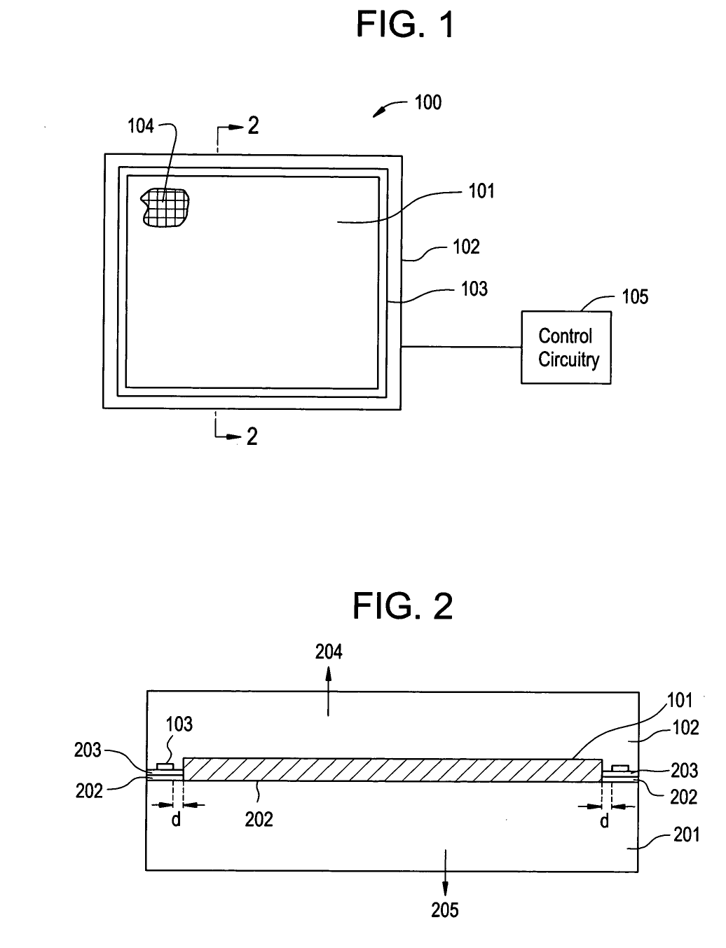

FIG. 1 is a top-view of a sealed structure 100 in accordance with an example embodiment. The structure includes a material 101 that is visible in this example embodiment through a top of a first substrate 102. As will become clearer as the present description continues, the material 101 may be damaged if subjected to heat above a particular threshold temperature. Illustratively, the material is an organic polymer material that functions as an OLED material.

The first substrate 102 is attached to a second substrate (not shown in FIG. 1), with the material 101 disposed between. A seal 103 is disposed perimetrically about the structure 100 and between the first substrate 102 and the second substrate. As will become clearer as the present description continues, the seal 103 effectively protects the material 101 from oxygen, moisture, or other contaminants, by preventing a significant degree of penetration of such contaminants.

In an illustrative embodiment, the sealed structure is an OLED display. The OLED display includes electrical elements 104 in an arrayed fashion (shown in partial view in FIG. 1). The elements 104 are well known to one skilled in the art, and may include electrical circuits, circuit lines and electronic devices, such as complementary metal oxide semiconductor (CMOS) transistor switches, which may be thin-film devices. The electrical elements 104 are generally disposed beneath the OLED material and are arranged to form the picture elements (pixels) of the display. In operation, control circuit 105 supplies electrical signals to the elements 104. This results in the creation of images at the display surface. As the operation of OLED devices is both known and outside the scope of the present embodiments, details of the operation of OLED devices are omitted so as to not obscure the description of example embodiments.

In accordance with example embodiments described herein, the seal 103 is a solder material that effects a bond between the first substrate 102 and the second substrate. Illustratively, the solder material is reflowed by an inductive heating using an electromagnetic field, such as radio frequency (RF) radiation. Beneficially, the RF field inductively couples with and heats the solder to create a metallurgical bond to form the seal, but does not generate appreciable heat in the other materials of the structure 100. As such, there is substantially no deleterious heating of the material 101. Moreover, because the heating of the sealing process of the example embodiments is highly localized, the material 101 may be within approximately 10.0 mm to approximately 2.0 mm of the seal 103, or less. This fosters substantially optimal use of the area of the structure 100.

FIG. 2 is a cross-sectional view of the structure 100 along the line 2-2 of FIG. 1. As shown, the structure 100 includes the first substrate 102 and a second substrate 201 with the material 101 disposed therebetween. The seal 103 bonds the two substrates together upon, and is disposed at a distance, d, from the material. Illustratively, this distance (d) is approximately 2.0 mm or less to approximately 10.0 mm.

The first and second substrates 102 and 201, respectively, are illustratively display-quality glass. In accordance with example embodiments, the glass materials may be from a wide variety of known glass materials, from float glass to fusion drawn glass. In certain example embodiments, the glass used for the first and second substrates is one of 1737™ or Eagle 2000™ glass manufactured by Corning Incorporated, Corning, N.Y. It is emphasized that the glass materials referenced are merely illustrative, and are in no-way limiting. Of course, in the example embodiments where the structure is incorporated in a display or lighting device, one or both of the substrates 102, 201 must be substantially transparent at the viewing wavelength of light. Moreover, it is noted that the first and second substrates need not be made of the same material. Finally, in other example embodiments, the substrates are not glass, but rather are another type of material, such as known packaging materials of the semiconductor and photonics arts. These materials and the components they house may be subject to the same temperature constraints and sealing requirements such as those described above, and thus would benefit from the sealing techniques, materials and apparati of the example embodiments.

Electrical connections may be made to the electrical elements 104 via one or more of a plurality of circuit lines 202. In operation, the OLED material 101 is driven by electrical signals from the circuit lines 202, resulting in the selective emission of light 204 in the case of a top emitter device, or the emission of light 205 in the case of a bottom emitter device, or both.

The circuit lines 202 are connected to control circuitry 105 that is external to the structure 100. Therefore, the circuit lines 202 must be electrically isolated from the seal 103 in order to avoid shorting of the circuit lines 202. In an example embodiment, this electrical isolation is effected by providing a layer of electrically insulating material 203 over the second substrate 201 and between the lines 202 and the seal 103. Illustratively, the insulating material 203 may be silicon nitride or silicon dioxide or any number of suitable electrically insulating materials amenable to the deposition techniques being employed.

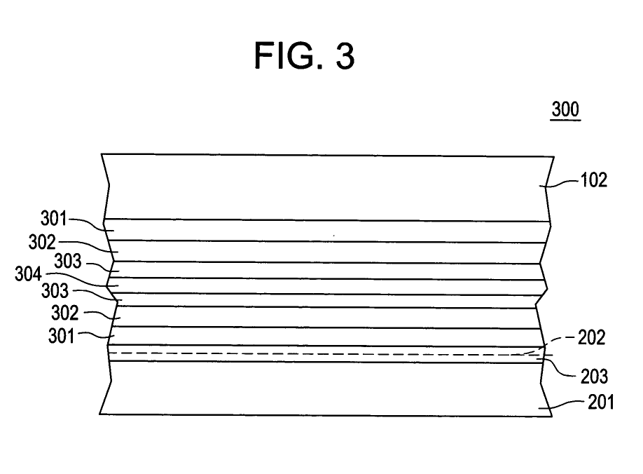

FIG. 3 is a partial cross-sectional view of a layered structure 300 in accordance with an example embodiment. The layered structure 300 will result in a seal (e.g., seal 103) between the first and second substrates upon induction heating using an electromagnetic field in accordance with an example embodiment. As will become clearer as the present description continues, the solder used in the sealing method of the example embodiments is used as the susceptor to the induction (dynamic magnetic) fields. This allows the solder to heat up, reflow, and wet the metallized surfaces without significantly heating the other elements of the structure, particularly temperature sensitive materials, such as OLED materials.

In an example embodiment in which the first substrate 102 and the second substrate 201 are glass, prior to deposition of the materials of the layers of the seal 103, the glass surfaces are cleaned by techniques that vary from the glass type to glass type. For most glass compositions the typical cleaning process consists of a series of cleaning steps using organic solvents. The parts are then plasma cleaned, using methods and gases typically known to those of ordinary skill in the art, before any coatings are deposited.

Initially, a layer of indium tin oxide (ITO) (not shown) is disposed over the second substrate 201 using known methods and is patterned by standard techniques to form the circuit lines 202. The circuit lines 202 have a thickness on the order of approximately 75 nm to approximately 80 nm and may be ordered, having a pitch of approximately 5 nm to approximately 6 nm. Next, an insulative layer 203 is disposed about the lines 202 to prevent shorting. The insulative layer 203 may be a layer of SiO₂, Si₃N₄, Al₂O₃ or other suitable electrical insulator. The insulative layer 203 has a thickness great enough to provide electrical isolation. The insulative layer 203 may be disposed over the second substrate 201 by methods well-known to one of ordinary skill in the art.

Next, an adhesion layer 301 is disposed over the insulative layer 203 as shown. The adhesion layer 301 illustratively is a layer of Al deposited as Al₂O₃ at a thickness of approximately 150 Å to approximately 315 Å. In an example embodiment, the adhesion layer 301 is deposited by resistive thermal evaporation. It is noted that other chemical and physical deposition methods may be used to deposit the adhesion layer 301 or any of the metal layers of the example embodiments that may be used as the adhesion layer. Assistive methods such as electron-beam and ion assist methods may also be used to deposit layer 301.

It is further noted that the adhesion layer 301 may be one or more of a variety of materials useful in fostering a bond between the metal layers of the seal and the glass of the substrates 102 and 201. Illustratively, these materials include Ti-based materials and Cr-based materials, which are well known for their adhesion properties to glass.

After the deposition of the adhesion layer 301, a bonding layer 302 is formed. Illustratively, the bonding layer 301 is nickel (Ni) having a thickness of approximately 3500 Å to approximately 7500 Å, and is deposited by resistive thermal evaporation. Again, other methods within the purview of one of ordinary skill in the art may be employed to deposit this and any of the other layers of the seal 103. The bonding layer 302 forms the metallurgical bond to a solder layer 304, thereby allowing the formation of the hermetic seal.

After the deposition of the bonding layer 302, a retarding layer 303, preferably gold, is disposed at a thickness of approximately 750 Å to approximately 1333 Å, formed by resistive thermal evaporation or another suitable method. This layer retards the oxidation of the nickel layer 302, which can adversely impact the bonding capability of the nickel.

Next, a solder layer 304, beneficially a perform layer, is disposed over the retarding layer 303 at a thickness of approximately 0.001″. The solder preform layer 304 may be one of a variety of materials. To wit, any a variety of alloys can be caused to reflow when coupled with an electromagnetic field of the correct induction frequency. Illustratively, SnAg (96.5/3.5) with a melting point of 221° C. was selected for its wetting abilities, its lead-free composition, and its relatively low melting temperature. Alternatively, a SnPb eutectic solder alloy may be used as the solder layer 304 and is beneficial in forming hermetic seals. Of course, other solder alloys can be used in this process. The alloys chosen must be able to maintain hermeticity after being subjected to a number of environmental conditions. Alloys with melting points lower than the SnPb eutectic (183° C.) can be readily substituted simply by making adjustments to the applied electromagnetic field used in the sealing process.

It is noted that solder alloys with melting points higher than 183° C. may be used, but the tooling will need to be modified to incorporate external cooling in order to keep the OLED area below a threshold temperature (e.g., 85° C.) during the soldering operation. Again, it is emphasized that the RF induction reflow process of the example embodiments can be optimized to reflow most of the many solder alloys used for fluxless soldering including many of the lead-free alloys.

The deposition of the layers 301-303 is repeated for the first substrate. Thereafter, the first and second substrates 102 and 201, respectively, are disposed over one another, with the solder preform layer 304 between the respective layers 301-303.

It is noted that the thickness of the various metal layers varies according to the metallization scheme used (e.g., Al, Ni, Au—Ti, Ni, Au—Cr, Ni, Au), the aspect ratio of the parts to be sealed, the length of the joints and the type of solder selected for the application.

After completion of the deposition of the layers of the seal 103, an inductive heating sequence in accordance with a method of an example embodiment is carried out. This example embodiment and an apparatus for the inductive heating according to an example embodiment are described presently.

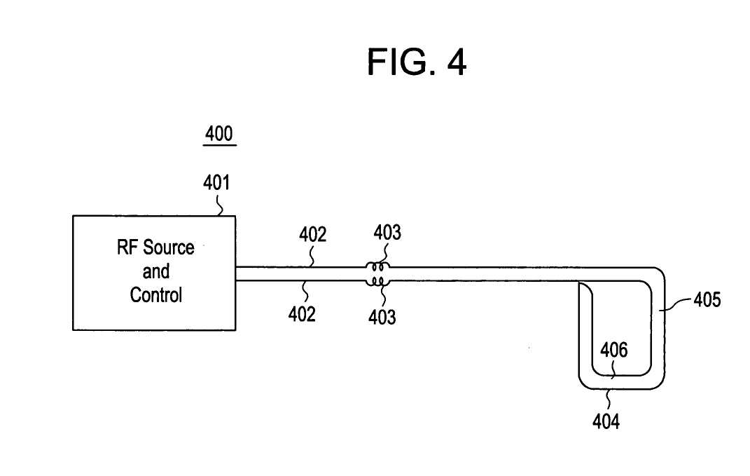

FIG. 4 is a schematic diagram of an apparatus 400 for sealing the first and second substrates 102 and 201, respectively, according to an example embodiment. Beneficially, the apparatus 400 selectively heats and melts layer 304 of the embodiment of FIG. 3, thereby creating a metallurgic bond and a hermetic seal.

The apparatus 400 illustratively includes a radio frequency (RF) source and controller 401 that provides an RF signal to the leads 402. The RF source and controller 401 may be one of a variety of known devices useful in applying an RF signal of a chosen frequency and power. It is emphasized that the use of RF electromagnetic waves is merely in accordance with an example embodiment. Clearly, other example embodiments may include the use of frequency bands of the electromagnetic spectrum beside the RF band. Illustratively, microwave frequency electromagnetic radiation may be used. The source and controller may require modification to include the desired electromagnetic frequency source and a suitable controller for the source. As these modifications are readily accomplished by one of ordinary skill in the art, their details are omitted so as not to obscure the description of example embodiments.

In operation, current delivered from the source 401 to the leads 402 traverses the coils 403, the inner loop 406 and the outer loop 404, resulting in a highly localized dynamic magnetic field (the induction field) in the region 405 substantially between the loops 404 and 406. This highly localized field has a frequency chosen to match a resonant or characteristic frequency of the solder preform layer 304, which melts and creates the bonds to the other layers, particularly the bonding layer 302. Ultimately, this results in the formation of a metallurgic bond and hermetic seal between the substrates.

The energy in the induction field supplied through the coils 404 and 406 sufficiently excites the materials in the metallization and solder layers resulting in the melting of the solder 304 and the subsequent bonding of the solder to the bonding layer 302. The loops 404 and 406 are designed so that the RF field generated confines most of its energy between the leads of the coil loop (i.e., region 406) where the field can couple with the material to be.

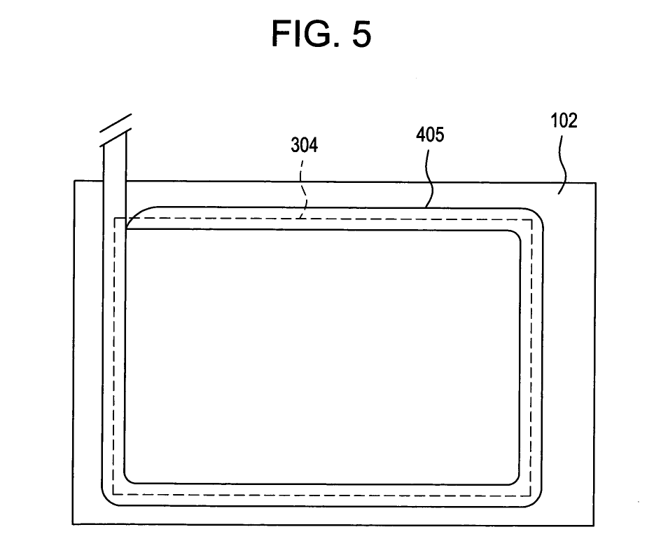

As stated, in order to effect the formation of the hermetic bond, the region 405 is disposed over the substrates 102, 201 so the layers 301-304 are within the region 405. This arrangement is shown more closely in FIG. 5. In this example embodiment, the region 405 is disposed over the first substrate 102, the solder layer 304 and the layers beneath and above the solder layer 304. With this alignment, the RF source and controller 401 generate the induction field concentrated in the region 405 to reflow the solder and form the seal 103.

In one illustrative embodiment, the RF source and controller provides an RF frequency of approximately 14.6 MHz at a power of approximately 600 W. In another illustrative embodiment, the RF frequency is approximately 13.7 MHz at a power of approximately 850 W. The applied frequency and power are based on a number of factors including metallization thickness and composition, solder thickness, composition, and the reflow properties of the solder alloy. In the example embodiments, good wetting and adherence results, along with a joint that showed no visual defects under 100× magnification.

The processing time is on the order of approximately 6 seconds to approximately 8.0 seconds regardless of the size of the substrates being sealed. Moreover, it is noted that the sealing may be accomplished in as little as approximately 1.0 seconds in some embodiments. This is a distinct advantage that the RF sealing has over some of the other candidate processes. By known laser sealing methods, the time to seal increases proportionately as the perimeter of the device to be sealed increases. Thus, known methods can be exceedingly time consuming and inefficient from a production standpoint. Finally, it is emphasized that the sealing parameters described are merely illustrative of the embodiments. Clearly, other frequency/power combinations and processing times may be used in keeping with the example embodiments.

As referenced previously, the methods and apparati of the example embodiments provide hermetic sealing of temperature-sensitive material (e.g., OLED material), while preventing the temperature-sensitive material from being heated beyond a safe threshold. Illustratively, measurements of the temperature during and after the inductive heating process of an example embodiment reveal a maximum temperature of less than 65° C. within 1.0 mm of the OLED material. As such, by virtue of the example embodiments, material 101, including OLEDs that can be damaged if subject to temperatures greater than a certain threshold temperature may be safely sealed.

Furthermore, the seals achieved via the example embodiments meet or exceed Bellcore® hermeticity standards. To wit, current requirements in the OLED industry require that a leak rate of no more than 1 μg of H₂O per m² per day @ 38° C. 90% RH. Leak rates of H₂O in the range of approximately 1.0×10⁻⁶ atm cc/sec to approximately 2.0×10⁻⁶ atm cc/sec were achieved via the example embodiments. In addition, the permeation of O₂ through the metal seal is negligible between room temperature and 100° C. To wit, the permeation of oxygen in seals formed in accordance with the example embodiments is less than 10⁻³ ml/m²/day.

As referenced previously, the methods of the example embodiments provide ease of manufacture. In addition to the benefits mentioned thus-far, the apparatus of FIG. 4 is versatile, being readily adapted to seal structures over a great range of sizes. For purposes of illustration, the structures may be approximately 2″×2″ or approximately 6″×6″ or greater. The higher end of the size of the device to be sealed is limited only by the feasibility of making a larger coil and the availability of a power supply to energize it. Moreover, the sealing process of example embodiments requires only seconds to complete, making it attractive for large-scale production. Furthermore, multiple induction coils can be fed from one power supply and RF source and control which foster scaling production to larger glass sheet sizes. Sealing speed, as mentioned above is not impacted by the scale of the production. The process of the example embodiments lends itself to scale up for both, large sheet type and small discreet part, in-line operations.

The example embodiments having been described in detail in connection through a discussion of exemplary embodiments, it is clear that modifications of the invention will be apparent to one having ordinary skill in the art having had the benefit of the present disclosure. Such modifications and variations are included in the scope of the appended claims.

1. A device, comprising:
a temperature-sensitive material disposed between a first substrate and a second substrate; and
a seal comprising a metal that is disposed perimetrically between the first and second substrates.

2. A device as recited in claim 1, further comprising at least two electrical conductors in electrical contact with the temperature sensitive material.

3. A device as recited in claim 2, wherein the electrical conductors are connected to circuitry that is external to the device.

4. A device as recited in claim 3, wherein an electrically insulating layer is disposed between the metal-containing seal and the electrical conductors.

5. A device as recited in claim 1, wherein the temperature-sensitive material is an organic light emitting device (OLED) material and the device is a lighting device.

6. A device as recited in claim 1, wherein the temperature-sensitive material is an electronic material.

7. A device as recited in claim 1, wherein the temperature-sensitive material is a photonic material.

8. A device as recited in claim 1, wherein the first substrate is a glass material.

9. A device as recited in claim 1, wherein the second substrate is a glass material.

10. A device as recited in claim 1, wherein H₂O penetrates the seal at a rate that is not more than approximately 2.0×10⁻⁶ atm cc/sec.

11. A device as recited in claim 1, wherein the metallic-seal contains a solder material.

12. A device as recited in claim 11, further comprising a bonding layer that creates a metallurgic bond to the solder material.

13. A method of fabricating a device, the method comprising:
providing a temperature-sensitive material between a first substrate and a second substrate; and
applying an electromagnetic field, which inductively heats a metal-containing layer that is disposed between the first and second substrates without heating the temperature-sensitive material to a temperature greater than a threshold temperature.

14. A method as recited in claim 13, wherein the inductive heating further comprises applying electromagnetic radiation to a selected region between the first and second substrates.

15. A method as recited in claim 14, wherein the electromagnetic field is in the radio frequency (RF) band.

16. A method as recited in claim 13, wherein the wherein the temperature-sensitive material is an organic light emitting device (OLED) material.

17. A method as recited in claim 13, wherein the temperature-sensitive material is an electronic material.

18. A method as recited in claim 13, wherein the temperature-sensitive material is a photonic material.

19. A method as recited in claim 13, wherein the first substrate is a glass material.

20. A method as recited in claim 13, wherein the second substrate is a glass material.

21. A method as recited in claim 13, wherein H₂O penetrates the seal at a rate that is not more than approximately 2.0×10⁻⁶ atm cc/sec.

22. A method as recited in claim 14, wherein the metallic-seal comprises a solder material.

23. A method as recited in claim 22, wherein the electromagnetic field has a frequency that substantially matches a resonant frequency of the solder material.

24. A display device, comprising:
an organic light emitting device (OLED) material disposed between a first substrate and a second substrate; and
a seal comprising a metal that is disposed perimetrically between the first and second substrates.

25. A display device as recited in claim 24, further comprising at least two electrical conductors in electrical contact with the temperature sensitive material.

26. A display device as recited in claim 25, wherein the electrical conductors are connected to circuitry that is external to the device.

27. A display device as recited in claim 26, wherein an electrically insulating layer is disposed between the metal-containing seal and the electrical conductors.

28. A display device as recited in claim 24, wherein the first substrate is a glass material.

29. A display device as recited in claim 24, wherein the second substrate is a glass material.

30. A display device as recited in claim 24, wherein H₂O penetrates the seal at a rate that is not more than approximately 2.0×10⁻⁶ atm cc/sec.

31. A display device as recited in claim 24, wherein the metallic-seal contains a solder material.

32. A display device as recited in claim 31, further comprising a bonding layer that creates a metallurgic bond to the solder material.
